(19) United States
(12) Patent Application Publication
(10) Pub. No.: US 2014/0146496 A1
(43) Pub. Date: May 29, 2014

(54) CONNECTING MECHANISM AND ELECTRONIC DEVICE WITH SAME

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventors: ZHI-YONG CAO, Shenzhen (CN); TENG-CHIAO SHEN, New Taipei (TW); BAO-SHAN ZHANG, Shenzhen (CN)

(73) Assignees: HONG FU JIN PRECISION INDUSTRY (ShenZhen) CO., LTD, Shenzhen (CN); HON HAI PRECISION INDUSTRY CO., LTD., New Taipei (TW)

(21) Appl. No.: 14/092,932

(22) Filed: Nov. 28, 2013

(30) Foreign Application Priority Data
Nov. 29, 2012 (CN) 2012206427401

(51) Int. Cl. H05K 7/02

(52) U.S. Cl. CPC H05K 7/02
USPC 361/759; 411/368; 136/251

(57) ABSTRACT

A connecting mechanism which is adjustable in respect of length and which retains its proper fastening function in various orientations connects a first body with a second body and includes a connecting piece, a bolt, and a nut. The connecting piece includes a circular bowl-shaped receiving groove which is open at a lower opening. The connecting flange is fastened to the first body via a threaded screw. The bolt has a spheroidal connecting head and a threaded connecting pole extending from the connecting head and protruding from the lower opening of the receiving groove to connect to and fasten the second body.

### TECHNICAL FIELD

The disclosure generally relates to mechanisms, and more particularly to a connecting mechanism for fastening an electronic device to a holding structure.

### DESCRIPTION OF RELATED ART

An electronic device may includes a base and a number of working units assembled on/to the base. Each of the working units can held by a number of different holders on the base. The working unit is fastened to each of the holders via a threaded bolt passing through a first assembly hole on the holder and a second assembly hole on the electronic device. However, if one of the holders is inaccurately made, such as an extending direction of the holder deviates from the extending direction of the standard holder or if the holder is shorter than a height of the standard holder, the first assembly hole cannot be aligned with the second assembly hole, and the working unit cannot be fastened to the holder by the threaded bolt. Thus, the holders must be made precisely, which leads to high manufacturing cost of the holders.

Therefore, it is desirable to provide a means which can overcome the above-mentioned problems.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding portions throughout the several views.

FIG. 1 is an isometric view of an electronic device in accordance with an exemplary embodiment of the present disclosure.

FIG. 2 is an exploded, isometric view of the electronic device of FIG. 1, the electronic device including a holder, a number of working units, and a connecting mechanism connecting the working unit with the holder.

FIG. 3 is an assembled, side view of the electronic device of FIG. 2.

FIG. 4 is an assembled, top view of the electronic device of FIG. 3.

FIG. 5 is similar to FIG. 3, but showing the holder deviating from a perpendicular direction.

FIG. 6 is similar to FIG. 3, but showing the holder being shorter than the height of the standard holder.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

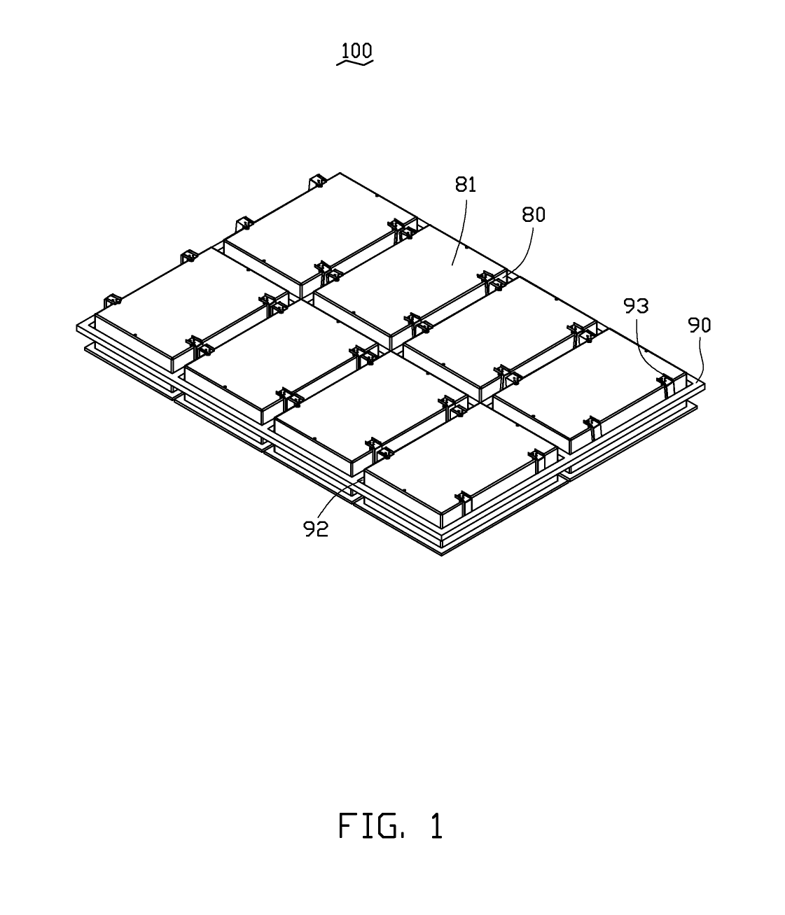

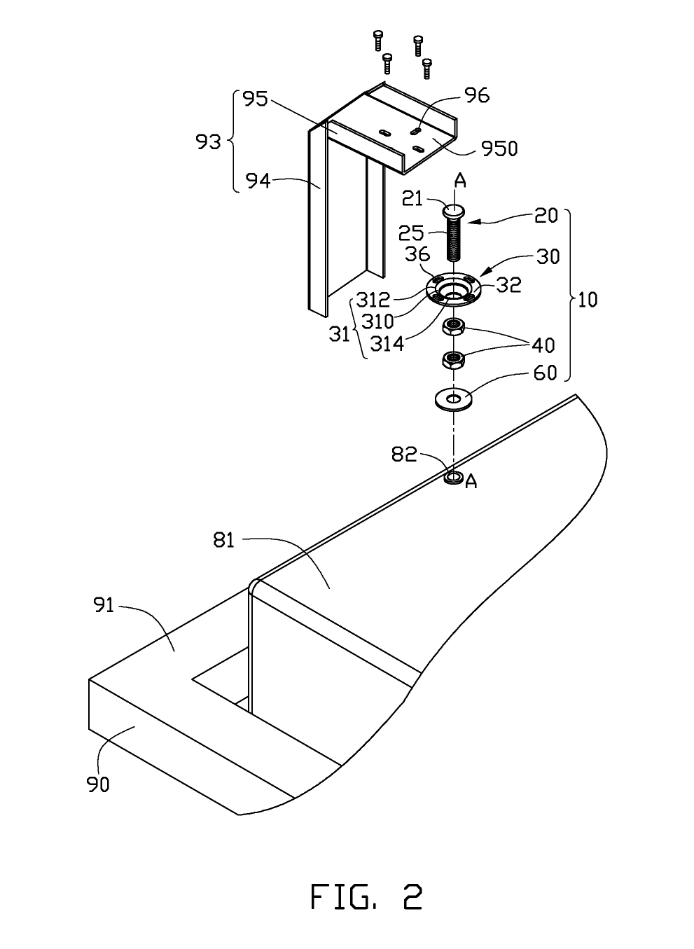

In FIGS. 1 and 2, an electronic device 100 in accordance with an exemplary embodiment includes a base 90 and a number of working units 80. The base 90 defines a number of receiving through holes 92 to receive the working units 80. The base 90 includes a number of holders 93 formed at a periphery of each of the receiving through holes 92. Each of the working units 80 is received in a receiving through hole 92. A top surface 81 of the working unit 80 is fastened to the holder 93 via a connecting mechanism 10. The holders 93 are symmetrical about a center of the receiving through hole 92. Thus, weight of the working unit 80 is equally taken by the holder 93 received in the same receiving through hole 92. In this embodiment, the receiving through hole 92 is rectangular. There are two holders 93 formed at each of a pair of parallel long sides of the receiving through hole 92. The working unit 80 can be a solar energy collector.

Each of the holders 93 includes a connecting part 94 and a holding part 95. One end of the connecting part 94 is fixed to the periphery of the receiving through hole 92. The holding part 95 horizontally extends towards an inner side of the receiving through hole 92 from the other end of the connecting part 94 away from the periphery of the receiving through hole 92. The holding part 95 includes a holding plate 950 which is parallel to an upper surface 91 of the base 90. The holding part 95 defines a number of fastening through holes 96 in the holding plate 950. The fastening through holes 96 are located near an end of the holding plate 950 away from the connecting part 94. Each of the fastening through holes 96 is substantially retangular and includes a pair of opposite round ends. The fastening through holes 96 are radial in shape around a center and are evenly spaced from each other.

The connecting mechanism 10 includes a connecting piece 30, a bolt 20, a pair of nuts 40, and a washer 60. The connecting piece 30 includes a receiving groove 31 and a connecting flange 32. The receiving groove 31 is hollow and bowl-shaped. The receiving groove 31 includes a spherical sidewall 310 and defines an upper opening 312 and a lower opening 314 at opposite ends of the spherical sidewall 310. Each of the upper opening 312 and the lower opening 314 is circular. Diameter of the upper opening 312 is greater than diameter of the lower opening 314. Center of the lower opening 314 is concentric with center of the upper opening 312. The sidewall 310 protrudes outwards from an inside of the receiving groove 31. The connecting flange 32 extends from a periphery of the upper opening 312. The connecting piece 30 defines a number of connecting through holes 36 in the connecting flange 32 corresponding to the fastening through holes 96. Each of the connecting through holes 36 is substantially retangular and includes a pair of opposite round ends. A longitudinal direction of the connecting through hole 36 is substantially parallel to a tangent from the outer circular periphery of the upper opening 312. The connecting through holes 36 are evenly spaced from each other. In this embodiment, there are four connecting through holes 36 defined in the connecting flange 32.

The bolt 20 includes a connecting head 21 and a connecting pole 25 extending from the connecting head 21. The connecting head 21 is substantially a spheroid. The maximum diameter of the connecting head 21 is less than the diameter of the upper opening 312 but greater than the diameter of the lower opening 314. The connecting pole 25 extends from a center of a bottom surface of the connecting head 21. The connecting pole 25 is substantially a cylinder. A diameter of the connecting pole 25 is less than the diameter of the lower opening 314. The connecting pole 25 includes a screw thread formed on an outer surface of the connecting pole 25.

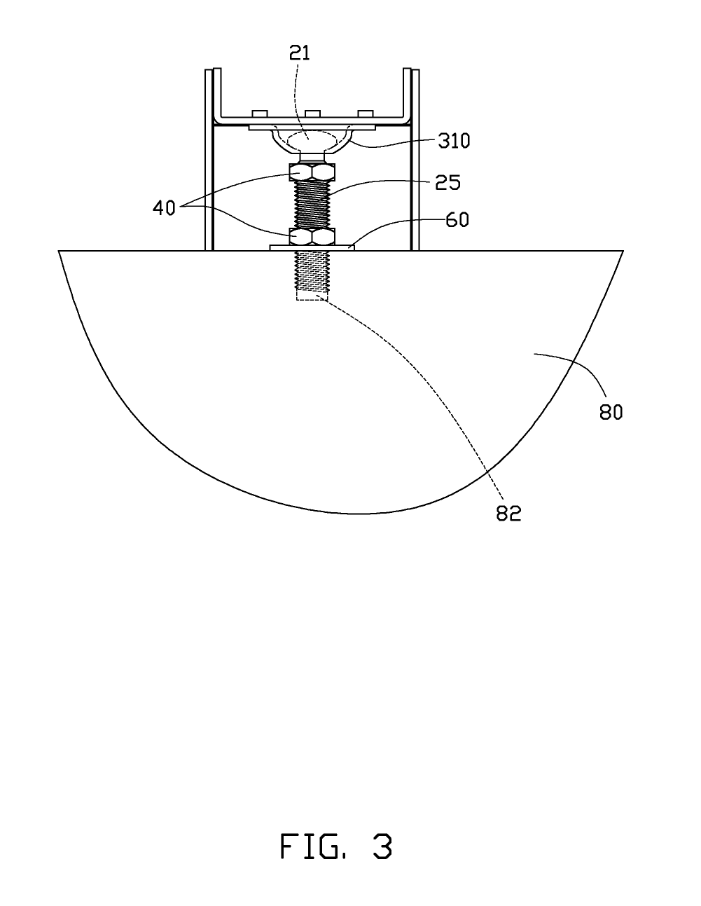

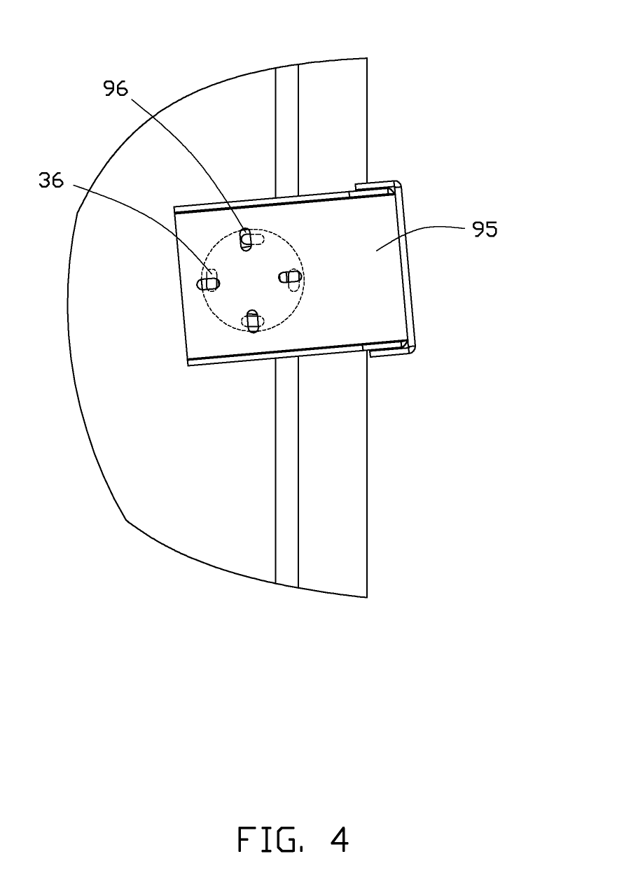

In assembly, referring to FIGS. 2, 3 and 4, the connecting pole 25 protrudes out of the receiving groove 31 via the lower opening 314. The connecting head 21 is cradled by the periphery of the lower opening 314 and securely accommodated in the receiving groove 31. The connecting flange 32 is in contact with a bottom surface of the holding plate 950. The connecting through holes 36 are aligned to the fastening through holes 96. The connecting piece 30 is fastened to the holding plate 950 by a number of threaded screws passing through the connecting through holes 36 and the fastening through holes 96. The longitudinal direction of each connecting through hole 36 is substantially perpendicular to the longitudinal direction of each fastening through hole 96. Thus, the connecting piece 30 can articulate relative to the holding plate 950 through a range of orientations.

The nuts 40 are screwed on the screw threads of the connecting pole 25. The washer 60 is sleeved on the connecting pole 25. An end of the connecting pole 25 is screwed into a threaded hole 82 defined on the top surface 81 of the working unit 80. The nut 40 close to working unit 80 is screwed towards the working unit 80 to fasten the working unit 80 on the bolt 20. The washer 60 is positioned between the nut 40 and the top surface 81 of the working unit 80 to avoid abrasion between the nut 40 and the base 90. The base 90 is thus fastened to the holder 93 via the connecting piece 30 and the bolt 20.

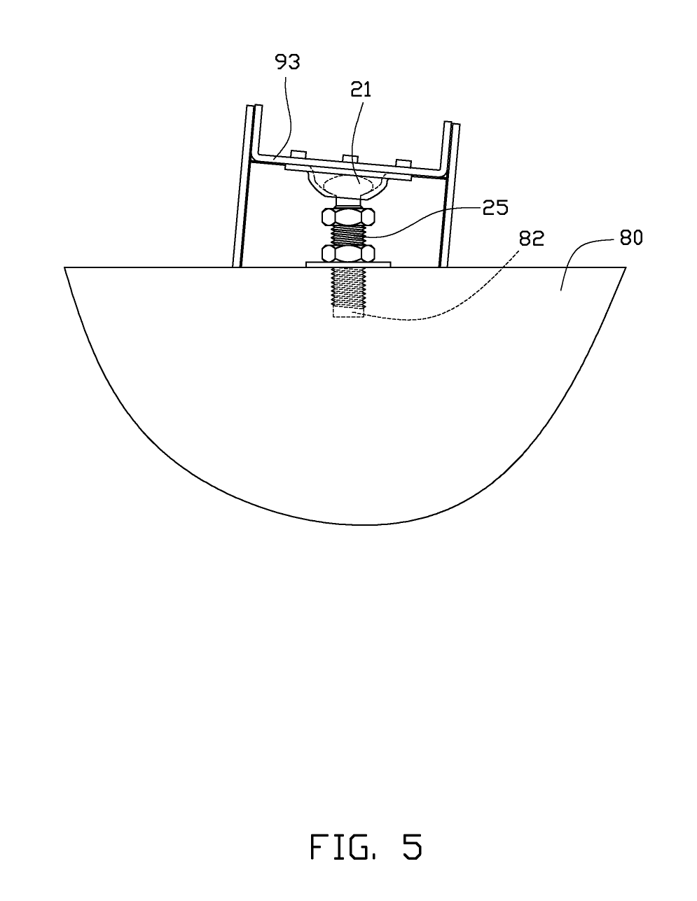

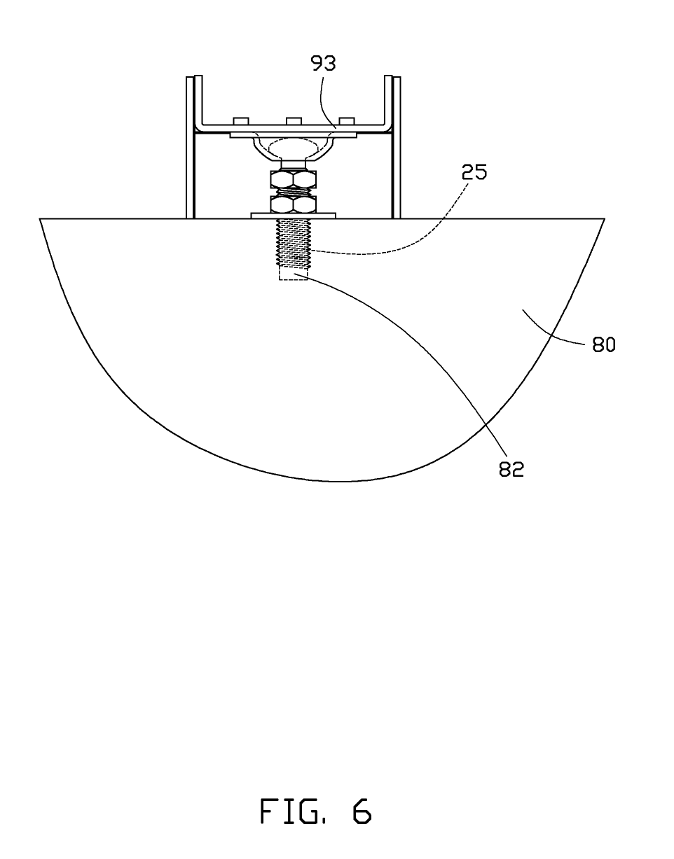

Referring to FIG. 5, the sidewall 310 of the receiving groove 31 being curved and the connecting head 21 being spherical, the connecting head 21 is capable of swinging in the receiving groove 31. The longitudinal direction of the connecting pole 25 is capable of being swung around the center of the lower opening 314. The extending direction of holder 93 may deviate from a perpendicular direction, the longitudinal direction of the connecting pole 25 can be other than vertical and still maintain a securing function with the base 90. In another situation, referring to FIG. 6, if the holder 93 is made shorter than the height of the standard holder 93, a part of the screwed length of the connecting pole 25 can be screwed into the base 90 to keep the base 90 horizontal.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A connecting mechanism for connecting a first body with a second body, the connecting mechanism comprising:
a connecting piece comprising a hollow bowel shaped receiving groove and a connecting flange, the receiving groove defining an upper opening and a lower opening at opposite ends of the spherical sidewall, and the connecting flange radially extending from a periphery of the upper opening;
a bolt comprising a spheroidal connecting head and a connecting pole extending from a bottom of the spheroidal connecting head, the spheroidal connecting head received in the receiving groove, and the connecting pole protruding out of the receiving groove via the lower opening; and
at least one nut;
wherein the connecting flange is fastened to the first body via at least one threaded screw, an end of the connecting pole away from the spheroidal connecting head is fastened to the second body via the nut, and the connecting head is swung in the receiving groove to adjust a longitudinal direction of the connecting pole when a position of the first body is changed relative to the second body.

2. The connecting mechanism of claim 1, wherein the receiving groove comprises a spherical sidewall, each of the upper opening and the lower opening is circular, a diameter of the upper opening is greater than a diameter of the lower opening, a center of the lower opening is concentric with a center of the upper opening, and the sidewall protrudes outwards from an inside of the receiveing groove.

3. The connecting mechanism of claim 1, wherein the first body defines at least one fastening through hole therein, the connecting piece defines at least one connecting through hole in the connecting flange corresponding to the fastening through hole, the connecting flange is in contact with the first body, the at least one connecting through hole is aligned with the at least one fastening through hole, and the threaded screw connects the connecting piece with the first body by passing through the connecting through hole and the fastening through hole.

4. The connecting mechanism of claim 3, wherein each of the connecting through hole and the fastening through hole is substantially rectangular and comprises a pair of opposite round ends, and a longidutinal direction of the connecting through hole is perpendicular to the longitudinal direction of the fastening through hole when the connecting through hole is aligned with the fastening through hole.

5. The connecting mechanism of claim 1, wherein the second body defines a threaded hole therein, the connecting pole comprises a screw thread formed on an outer surface of the connecting pole, the nut is screwed on the screw thread, the end of connecting pole away from the connecting head is screwed into the threaded hole, and the nut is screwed towards the second body to fasten the second body to the bolt.

6. The connecting mechanism of claim 1, further comprising a washer sleeved on the connecting pole and sandwiched between the nut and the second body.

7. An electronic device comprising:
a base defining a plurality of receiving through holes and comprising a plurality of holder formed at a periphery of each receiving through hole;
a plurality of working units correspondingly received in the receiving through holes;
and a plurality of connecting mechanisms connecting the working units with the holder, each of the connecting mechanisms comprising:
a connecting piece comprising a hollow bowel shaped receiving groove and a connecting flange, the receiving groove defining an upper opening and a lower opening at two opposite ends along a symmetric axis of the spherical sidewall, and the connecting flange radially extending from a periphery of the upper opening;
a bolt comprising a spheroidal connecting head and a connecting pole extending from a bottom of the spheroidal connecting head, the spheroidal connecting head received in the receiving groove, and the connecting pole protruding out of the receiving groove via the lower opening; and
at least one nut;
wherein the connecting flange is fastened to the holder via a plurality of threaded screws, an end of the connecting pole away from the spheroidal connecting head is fastened to a top surface of the working unit, and the connecting head is swung in the receiving groove to adjust a longitudinal direction of the connecting pole when a position of the holder is changed relative to the second body.

8. The electronic device of claim 7, wherein the holders are symmetrical about a center of the receiving through hole.

9. The electronic device of claim 8, wherein the receiving through hole is rectangular, and there are two holders respectively formed at each of a pair of parallel longe peripheries of the receiving through hole.

10. The electronic device of claim 8, wherein the working unit is a solar energy colletor.

11. The electronic device of claim 8, wherein each of the holder comprises a connecting part and a holding part, one end of the connecting part is fixed to the periphery of the receiving through hole, the holding part horizontally extends towards an inner side of the receiving through hole from the other end of the connecting part away from the periphery of the receiving through hole, and the working unit is connected to the holding part.

12. The electronic device of claim 11, wherein the holding part comprises a holding plate parallel to the upper surface of the base, the holding part defines a plurality of fastening through holes in the holding plate, the fastening through holes are located near an end of the holding plate away from the connecting part, the fastening through holes radially direct to a center, and the fastening through holes are evenly spaced from each other.

13. The electronic device of claim 12, wherein the connecting piece defines a plurality of connecting through holes in the connecting flange corresponding to the fastening through holes, the connecting flange is in contact with the holding plate, the connecting through holes are aligned with the fastening through holes, and the threaded screws connect the connecting piece with the holders by passing through the connecting through holes and the fastening through holes.

14. The electronic device of claim 13, wherein each of the connecting through hole and the fastening through hole is substantially rectangular and comprises a pair of opposite round ends, a longitudinal direction of each connecting through hole is substantially parallel to a tangent from the outer circular periphery of the upper opening, and a longidutinal direction of each connecting through hole is perpendicular to the longitudinal direction of the corresponding fastening through hole when the connecting through holes are aligned with the fastening through hole.

15. The electronic device of claim 7, wherein the receiving groove comprises a spherical sidewall, each of the upper opening and the lower opening is circular, a diameter of the upper opening is greater than a diameter of the lower opening, a center of the lower opening is aligned to a center of the upper opening, and the sidewall protrudes outwards Page 12 of 14 from an inside of the receiveing groove.

16. The electronic device of claim 7, wherein the working unit defines a threaded hole in the top surface corresponding to the holder, the connecting pole comprises a screw thread formed on an outer surface of the connecting pole, the nut is screwed on the screw thread, the end of connecting pole away from the connecting head is screwed into the threaded hole of the working unit, and the nut is screwed towards the working unit to fasten the working unit to the bolt.

17. The electronic device of claim 7, further comprising a washer sleeved on the connecting pole and sandwiched between the nut and the second body.

18. The electronic device of claim 7, wherein each of the working units is a solar energy collector.
